(19) United States
(12) Patent Application Publication
(10) Pub. No.: US 2008/0286929 A1
(43) Pub. Date: Nov. 20, 2008

(54) METHOD FOR MANUFACTURING SEMICONDUCTOR DEVICE

(75) Inventor: Toshihiko MIYASHITA, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/167,293

(22) Filed: Jul. 3, 2008

Related U.S. Application Data
(63) Continuation of application No. PCT/JP2006/300348, filed on Jan. 13, 2006.

(51) Int. Cl. H01L 21/8236

(52) U.S. Cl. 438/278; 257/E21.631

(57) ABSTRACT

The method for manufacturing a semiconductor device according to the invention includes the first doping step of doping source/drain regions including source/drain extension regions adjacent to a channel region of a MOS transistor, the second doping step of doping pocket implant regions disposed from the bottom of the source/drain extension regions in the depth direction, the step of forming an amorphous surface layer at the surface of a semiconductor crystal substrate so as to overlap the source/drain extension regions and the pocket implant regions, and the recrystallization step of recrystallizing the amorphous surface layer by a solid-phase epitaxy technique.

### TECHNICAL FIELD

This is related to methods for manufacturing a semiconductor device including a MOS transistor.

### BACKGROUND

The performance of MOS transistors is conventionally enhanced by reducing the channel width immediately under the gate electrode. It is however required that a so-called short channel effect, which is produced by downsizing, be prevented, while the performance of the MOS transistor enhanced by reducing the channel width is maintained. The short channel effect refers to the increase of leakage current occurring between the source region and the drain region with the channel region in between when the MOS transistor is in an off state.

Accordingly, it becomes required that the MOS transistor be downsized in the depth direction of the substrate to prevent the short channel effect. In addition, the structure of the MOS transistor must be changed around the source/drain regions.

More specifically, each of the source and drain regions includes a region in which a dopant is diffused deeply and a region adjacent to the channel region in which the dopant is diffused lightly (hereinafter referred to as “source extension region” or “drain extension region”). Right under the regions in which the dopant is lightly diffused, a dopant having a conductive type opposite to the dopant in the source/drain regions is diffused (the regions containing the dopant having an opposite conductive type hereinafter referred to as “pocket implant regions”).

The short channel effect can further be prevented by establishing a shallow junction in the source/drain extension regions. This is because a depletion layer is prevented from extending from the source/drain extension regions to the channel region in the MOS transistor, so that the electric field generated by the gate electrode controls almost all the channel region. Consequently, leakage current can be reduced, which is produced between the source region and the drain region when the MOS transistor is in an off state.

In order to prevent the dopant in the source and drain regions from being diffused by heat treatment for activating the dopant, dopant activation methods, such as LSA (laser spike annealing) or FLA (flash lamp annealing), have been proposed which combine amorphization of the source/drain regions and short-time heat treatment (for example, Patent Document 1). The amorphization of the source/drain regions is performed by ion implantation of a dopant for forming the source/drain regions and besides ion implantation of a type of atom neutralizing the silicon substrate, such as germanium (Ge).

Another dopant activation method has also been proposed which combines a process for uniformly amorphizing the source/drain regions and the above-described dopant activation (for example, Patent Document 2).

Patent Document 1: PCT Japanese Translation Patent Publication No. 2001-509316

Patent Document 2: PCT Japanese Translation Patent Publication No. 2005-510871

The pocket implant region is important to prevent the short channel effect. It is accordingly desired to prevent the dopant in the pocket implant region from rediffusing and to enhance the activation of the dopant, in addition to the formation of a shallow junction in the source/drain extension region.

This is because the pocket implant regions of a MOS transistor prevent a depletion layer from extending to the channel region from the dopant deeply diffused regions of the source/drain regions. The pocket implant regions suppress parasitic bipolar action occurring in the source region, the substrate region immediately under the gate electrode, and the drain region.

Unfortunately, if the above-described amorphization is applied to the pocket implant regions, amorphous layers round and intrude the channel of the MOS transistor. This is because the pocket implant region has a portion that rounds the channel region. Consequently, irregularities of the crystal lattice remain in the channel region to reduce the mobility of the carriers of the MOS transistor even after dopant activation, and thus the characteristics of the MOS transistor are degraded.

### SUMMARY

According to one aspect of the embodiments, the method for manufacturing a semiconductor device is provided. The method for manufacturing a semiconductor device is intended for manufacture of a semiconductor device including a MOS transistor. The method includes the first doping step of doping source/drain regions of the MOS transistor that include source/drain extension regions adjacent to a channel region of the MOS transistor; the second doping step of doping pocket implant regions formed from the bottom of the source/drain extension regions in the depth direction in a crystalline semiconductor substrate; the surface layer forming step of forming an amorphous surface layer at the surface of the semiconductor substrate so as to overlap the source/drain extension regions and the pocket implant regions; and the recrystallization step of recrystallizing the amorphous surface layer by a solid-phase epitaxy technique.

### BRIEF DESCRIPTION OF DRAWINGS

FIGS. 1A to 1C are representations of a dopant activation step performed by solid-phase epitaxial regrowth (SPER).

FIGS. 2A to 2D are representations of a process for manufacturing a MOS transistor.

FIGS. 3A to 3E are representations of a method for manufacturing a semiconductor device according to Embodiment 1.

FIGS. 4A to 4E are representations of the method for manufacturing a semiconductor device according to Embodiment 1.

FIGS. 5A to 5F are representations of a method for manufacturing a semiconductor device according to Embodiment 2.

FIGS. 6A to 6E are representations of the method for manufacturing a semiconductor device according to Embodiment 2.

FIGS. 7A to 7F are representations of a method for manufacturing a semiconductor device according to Embodiment 3.

FIGS. 8A to 8E are representations of the method for manufacturing a semiconductor device according to Embodiment 3.

FIGS. 9A to 9F are representations of a method for manufacturing a semiconductor device according to Embodiment 4.

FIGS. 10A to 10E are representations of the method for manufacturing a semiconductor device according to Embodiment 4.

### DESCRIPTION OF THE PREFERRED EMBODIMENTS

Embodiments 1 to 4 will now be described.

### Embodiment 1

Embodiment 1 relates to a method for manufacturing a semiconductor device including a MOS transistor having a “source extension region”, a “drain extension region”, and “pocket implant regions”. The method is intended to activate dopants in the source region, the drain region, and the pocket implant regions by heat treatment at a temperature to the extent that solid phase epitaxy occurs and is featured by forming an amorphous layer after forming a gate electrode.

The “source extension region” and the “drain extension region” are part of the source and drain regions respectively, and are adjacent to the channel region of the MOS transistor, and in which a dopant is shallowly diffused. The “pocket implant regions” are each disposed immediately under the “source extension region” or the “drain extension region”, and in which a dopant having a conductive type opposite to the dopant in the source region and the drain region is diffused.

The amorphous layer refers to a layer in which atoms are disorderly deposited, and may be called a “non-crystalline layer”. In the present embodiment, however, the amorphous layer may have a crystal lattice to some extent.

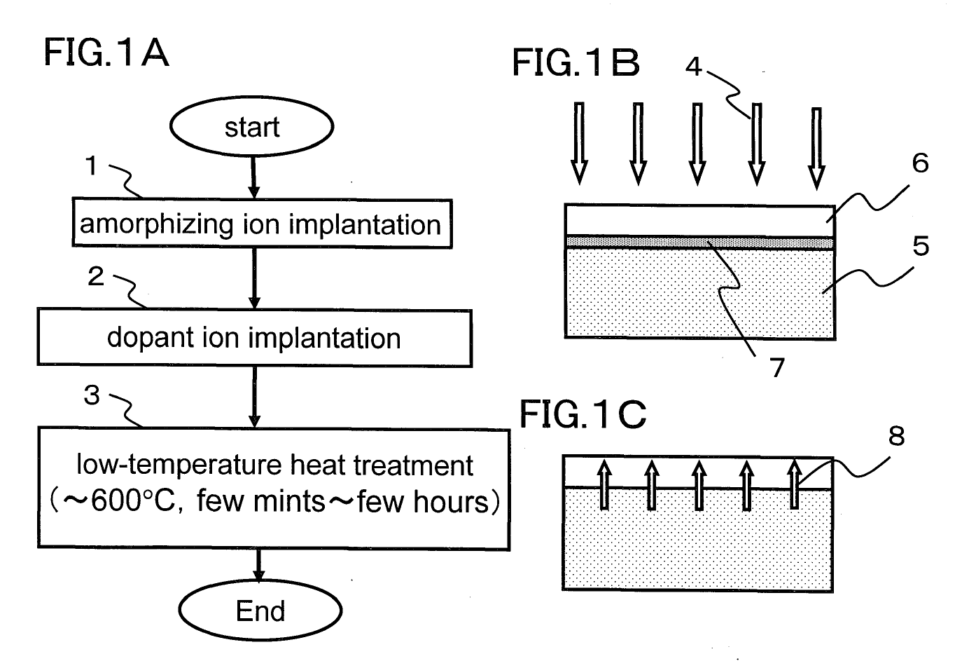

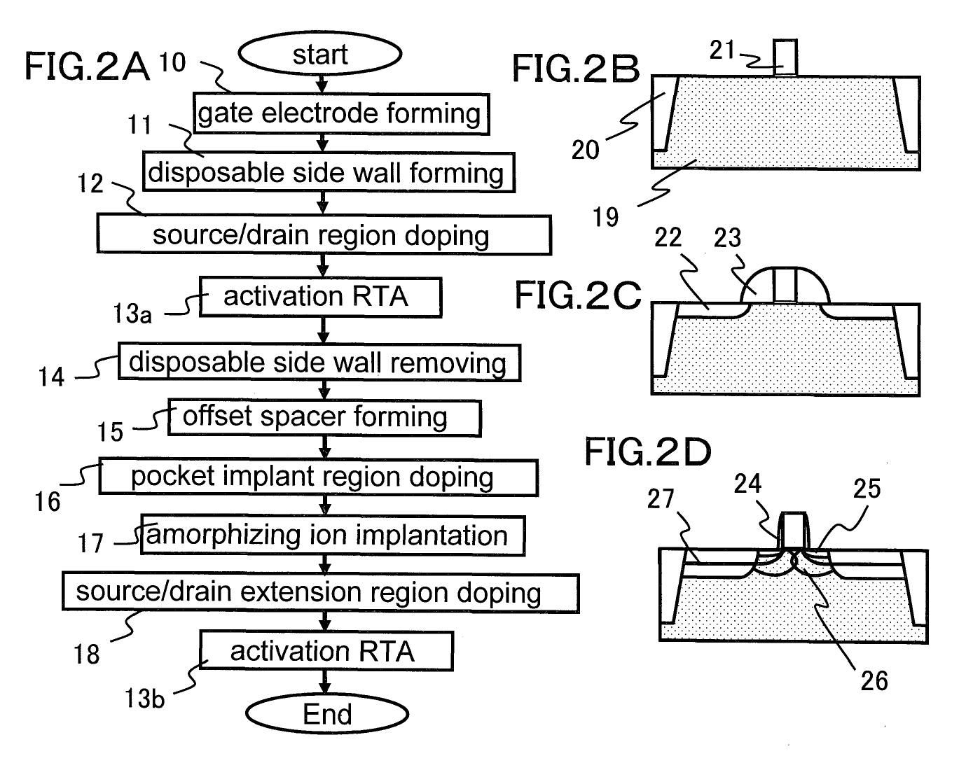

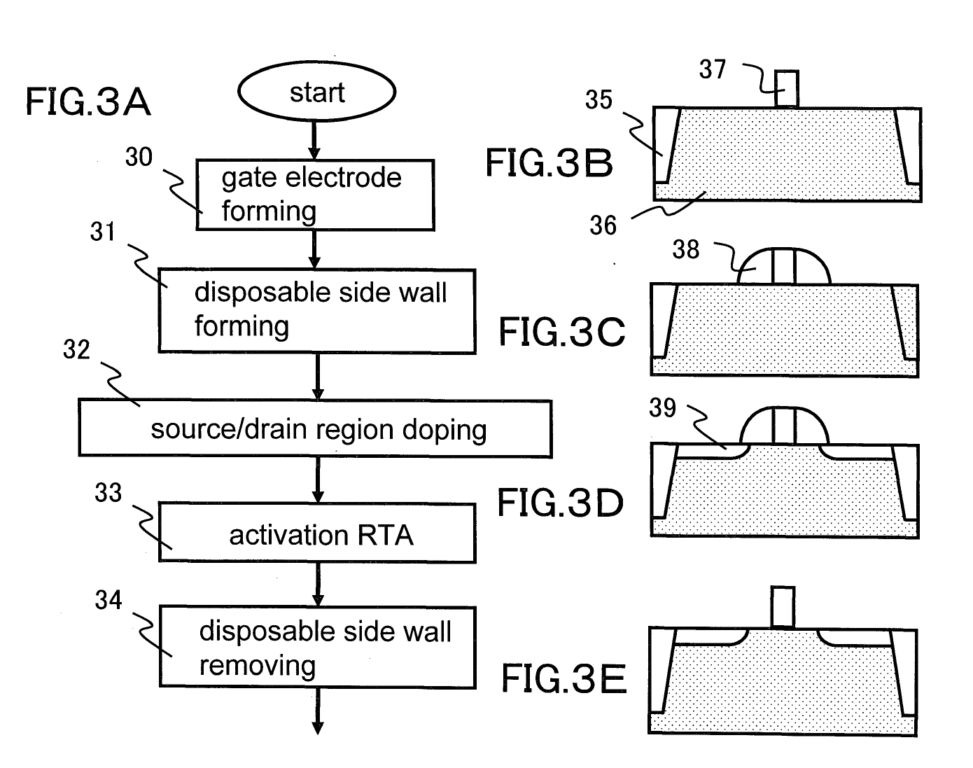

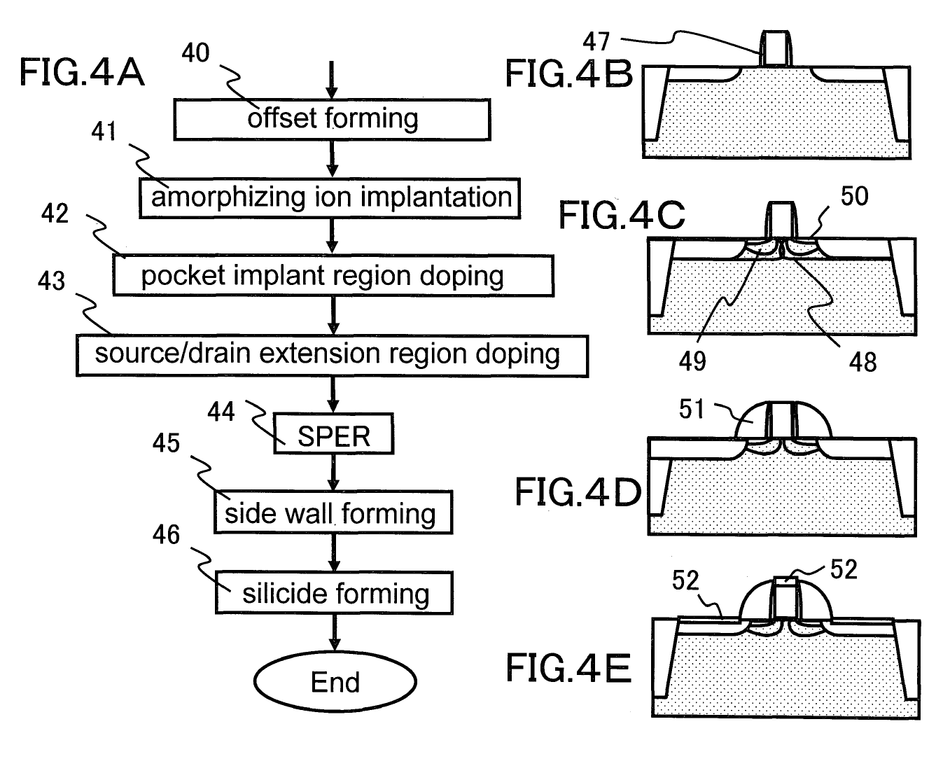

A dopant activation process performed by low-temperature solid-phase epitaxial regrowth will now be described with reference to FIGS. 1A to 1C. Also, disadvantages of the process for manufacturing a MOS transistor including the dopant activation process performed by low-temperature solid-phase epitaxial regrowth will be described with reference to FIGS. 2A to 2D. Then, Embodiment 1 will be described with reference to FIGS. 3A to 3E and 4A to 4E.

FIGS. 1A to 1C are representations of the dopant activation process performed by low-temperature solid-phase epitaxial regrowth (SPER).

FIG. 1A is a flow chart of the dopant activation process by low-temperature solid-phase epitaxial regrowth. FIG. 1A also shows that the dopant activation process performed by low-temperature solid-phase epitaxial regrowth includes an amorphizing ion implantation step 1, a dopant ion implantation step 2, and a low-temperature heat treatment step 3 performed to the extent that solid phase epitaxy occurs.

FIG. 1B is a representation of the amorphizing ion implantation step 1 and the dopant ion implantation step 2. FIG. 1B also shows amorphizing ion implantation 4, a semiconductor substrate 5, a doped layer 6, and an amorphous surface layer 7.

In the amorphizing ion implantation step 1, a type of atom or molecule is ionized and implanted into the semiconductor substrate 5 to break the crystal of the semiconductor substrate 5, thus forming the amorphous surface layer 7. For forming the amorphous surface layer 7 in a silicon crystal substrate, a type of homologous atom in the periodic table having a higher mass, such as germanium (Ge) or silicon (Si), may be used. Alternatively, a type of atom inactive in the silicon crystal and having a higher mass may be used, such as argon (Ar).

In the dopant ion implantation step 2, a dopant is ionized and ion-implanted into the semiconductor substrate 5 to form a doped layer 6. The amorphizing ion implantation step 1 may be performed before or after the dopant ion implantation step 2. If the region intended for the amorphous surface layer 7 is the same as the region intended for the doped layer 6, the dopant for forming the doped layer 6 may be ion-implanted to form the amorphous surface layer 7. In other words, the dopant ion implantation step 2 may double as the amorphizing ion implantation step 1.

FIG. 1C is a representation of the low-temperature heat treatment step 3 of performing heat treatment to the extent that solid phase epitaxy occurs. FIG. 1C shows the semiconductor substrate 5, the doped layer 6, and arrows 8 designating the direction of recrystallization. The low-temperature heat treatment step 3 is performed at a low temperature of about 500 to 650° C. over a period of several minutes to several hours after the step shown in FIG. 1B. The amorphous surface layer 7 is recrystallized in the direction of arrows 8 from the crystalline substrate by the low-temperature heat treatment, inheriting properties of the crystalline substrate. The recrystallization proceeds to the surface of the semiconductor substrate. This recrystallization is due to solid phase epitaxy.

In general, the dopant in the doped layer 6 is activated by heat treatment at a high temperature of about 900° C. or more. When solid phase epitaxy occurs with the doped layer 6 overlying the amorphous surface layer 7, however, the dopant in the doped layer 6 transcends the solubility limit and is activated even at a low temperature of about 600° C. This is because the occurrence of solid phase epitaxy allows the dopant in a nonparallel state to be taken in the crystal lattice and activated. Since the low-temperature heat treatment step 2 of performing heat treatment to the extent that solid phase epitaxy occurs is performed at a low temperature, the dopant is not thermally diffused, desirably.

FIGS. 2A to 2D are representation of a process for manufacturing a MOS transistor. A disadvantage of a MOS transistor manufacturing process including a dopant activation step performed by low-temperature solid-phase epitaxial regrowth will now be descried.

FIG. 2A is a flow chart of a process for manufacturing a MOS transistor using a disposable side wall. The MOS transistor manufacturing process includes a gate electrode forming step 10, a disposable side wall forming step 11, a source/drain region doping step 12, an activation RTA (Rapid Thermal Anneal) step 13a, a disposable side wall removing step 14, an offset spacer forming step 15, a pocket implant region doping step 16, an amorphizing ion implantation step 17, a source/drain extension region doping step 18, and an activation RTA step 13b.

The source/drain regions used herein each include a “dopant deeply diffused region” and a “source or drain extension region”. The “source/drain extension regions” are adjacent to the channel region of the MOS transistor, and “pocket implant regions” are disposed immediately under the “source/drain extension regions” and in the channel region.

FIG. 2B is a representation of the gate electrode forming step 10. The gate electrode forming step 10 includes the sub-step of preparing a semiconductor substrate 19 having an element isolation region 20, the sub-step of forming a gate insulating layer, the sub-step of forming an electrical conductor layer for an electrode, and the sub-step of etching the electrical conductor layer for the electrode to form a gate electrode 21 of the MOS transistor. The semiconductor substrate 19 is made of silicon crystal. The electrical conductor layer for the electrode is formed of polysilicon (P—Si).

FIG. 2C is a representation of the disposable side wall forming step 11, the source/drain region doping step 12, and the activation RTA step 13a. FIG. 2C shows the semiconductor substrate 19, the element isolation region 20, and the dopant deeply diffused region 22, and a disposable side wall 23.

The disposable side wall forming step 11 is performed after the formation of the gate electrode 21 and includes the sub-step of depositing, for example, a silicon oxide (SiO₂) insulating layer and the sub-step of anisotropically etching the insulating layer. The disposable side wall forming step 11 forms the disposable side wall 23 around the side walls of the gate electrode 21.

In the source/drain region doping step 12, a dopant is ion-implanted into the dopant deeply diffused region 22, which is part of the source/drain region. Since the disposable side wall 23 serves as a mask for ion implantation, the dopant deeply diffused region 22 is formed distant from the channel region of the MOS transistor. A Group V atom in the periodic table, such as arsenic (AS) or phosphorus (P), or a molecule formed by combining such an atom is used as the dopant for an N-type MOS transistor formed on a silicon substrate. On the other hand, a Group III atom in the periodic table, such as boron (B), or a molecule formed by combining such an atom, such as BF2 (boron fluoride), is used as the dopant for a P-type MOS transistor formed on a silicon substrate.

The activation RTA step 13a activates the dopant by spike-RTA using an RTA apparatus.

The spike-RTA refers to a heat treatment performed on the semiconductor substrate at such a sharp thermal gradient as increases the temperature to a level activating the dopant in a short time of several hundred milliseconds to several seconds. Since the time period in which a dopant activating temperature is held is substantially 0 seconds, the spike-RTA has a thermal profile like a spike. The dopant activating temperature is, for example, about 900 to 1050° C.

FIG. 2D is a representation of the disposable side wall removing step 14, the offset spacer forming step 15, the pocket implant region doping step 16, the amorphizing ion implantation step 17, the source/drain extension region doping step 18, and the activation RTA step 13b. FIG. 2D shows the semiconductor substrate 19, the element isolation region 20, the dopant deeply diffused region 22, an offset spacer 24, source/drain extension regions 25, pocket implant regions 26, and amorphized regions 27.

In the disposable side wall removing step 14, the disposable side wall 23 is removed by isotropic etching.

The offset spacer forming step 15 is performed after the disposable side wall removing step 14 and includes the sub-step of depositing, for example, a silicon oxide (SiO₂) insulating layer and the sub-step of anisotropically etching the insulating layer. As a result, the offset spacer 24 is formed on the side walls of the gate electrode 21. The offset spacer 24 has a smaller width than the disposable side wall 23. The name of offset spacer 24 comes from that a space is formed to slightly increase the width of the gate electrode 29 so as to complement the width (offset).

The offset spacer 24 is intended for use as a mask when a dopant is ion-implanted into the source/drain extension regions 25, as will be described later. The offset spacer 24 thus prevents the dopant implanted into the source/drain extension regions 25 from rounding and intruding the channel region of the MOS transistor.

In the pocket implant region doping step 16, a dopant is ion-implanted into the pocket implant regions 26. The pocket implant regions 26 are in contact with the bottom of the source/drain extension regions 25, and have a depth from the bottom in the depth direction of the substrate. However, the dopant for the pocket implant regions 26 may enter not only the lower portions of the source/drain extension regions 25, but also their sides, because ion implantation of the dopant into the pocket implant regions 26 is performed in a slanting direction forming an angle with respect to the surface of the substrate. In this instance, the dopant for forming the pocket implant regions 26 has a conductive type opposite to the dopant in the source/drain region. For an N-type transistor formed on a silicon semiconductor, for example, the dopant of the source and drain regions may be arsenic (As) or antimony (Sb) and the dopant of the pocket implant regions 26 may be boron (B) or indium (In).

In the amorphizing ion implantation step 17, a type of atom or molecule that can amorphize the crystal of the semiconductor substrate 19 is ionized and ion-implanted into the semiconductor substrate 19 to form the amorphized regions 27. In this instance, the amorphized regions 27 have a larger depth than the source/drain extension regions 25, but are not as deeper as a level reaching the bottom of the pocket implant region 26.

In the source/drain extension region doping step 18, the same dopant as in the dopant deeply diffuse regions 22 is implanted into the source/drain extension regions 25.

The activation RTA step 13b activates the dopants in the source/drain extension regions 25 and the pocket implant regions 26 by spike-RTA using an RTA apparatus.

The spike-RTA in the activation RTA step 13b performs heat treatment in the same manner as the spike-RTA in the preceding activation RTA step 13a. However, the activation RTA step 13b is performed at a temperature slightly lower than that in the preceding activation RTA step 13a in order to prevent the dopant from diffusing.

In the MOS transistor manufacturing process shown in FIGS. 2A to 2D, the pocket implant regions 26 are not amorphized by amorphizing ion implantation. Since the pocket implant regions 26 partially round and intrude the channel region of the MOS transistor, amorphizing ion implantation of the pocket implant regions 26 degrades the state of the crystal lattice of the channel region. Hence, the degradation of the crystal lattice of the channel region results in the degradation of the MOS transistor.

In the MOS transistor manufacturing process shown in FIGS. 2A to 2D, the activation of the dopant in the pocket implant regions 26 must be performed at a temperature of about 900° C. or more. Consequently, the dopant in the source/drain extension regions 25 is rediffused while the dopant in the pocket implant regions 26 is activated. Therefore, a dopant distribution in which the concentration of the dopant is sharply increased cannot be produced at the boundary of the source/drain extension regions 25.

As a result, the dopant from the source/drain extension regions 25 rounds and intrudes the channel region of the MOS transistor, thereby degrading the characteristics of the MOS transistor.

FIGS. 3A to 3E and 4A to 4E are representations of a method for manufacturing a semiconductor device according to Embodiment 1.

FIG. 3A is a flow chart showing the first half of the semiconductor device manufacturing method of Embodiment 1. FIG. 3A also shows that the semiconductor device manufacturing method of Embodiment 1 includes a gate electrode forming step 30, a disposable side wall forming step 31, a source/drain region doping step 32, an activation RTA step 33, and a disposable side wall removing step 34.

FIG. 3B is a representation of the gate electrode forming step 30. The gate electrode forming step 30 includes the sub-step of preparing a semiconductor substrate 36 having an element isolation region 35, the sub-step of forming a gate insulating layer, the sub-step of forming an electrical conductor layer for a gate electrode 37, and the sub-step of etching the electrical conductor layer to form the gate electrode 37 of the MOS transistor.

In the sub-step of preparing the semiconductor substrate 36 having the element isolation region 35, a groove is formed in the semiconductor substrate 36 and an insulating material is embedded in the groove.

In the sub-step of forming the gate insulating layer, the semiconductor substrate 36 is thermally oxidized in an oxygen atmosphere to form a gate oxide layer.

In the sub-step of forming the electrical conductor layer for the gate electrode 37, the electrical conductor layer is deposited on the semiconductor substrate 36 by CVD. Preferably, the electrical conductor layer is formed of, for example, polysilicon (P—Si).

The sub-step of etching the electrical conductor layer to form the gate electrode 37 of the MOS transistor includes forming a resist pattern for the gate electrode 37 on the electrical conductor layer, or the polysilicon (P—Si) layer, by photolithography, and etching the electrical conductor layer using the gate electrode 37 resist pattern as a mask. Thus, the gate electrode 37 is completed.

FIG. 3C is a representation of the disposable side wall forming step 31. FIG. 3C shows a disposable side wall 38.

The disposable side wall forming step 31 includes the sub-step of depositing an insulating layer at a constant thickness and the sub-step of anisotropically etching the insulating layer. Thus, the disposable side wall 38 is formed on the side walls of the gate electrode 37. The name of disposable side wall comes from that the disposable side wall 38 will be disposed of without remaining until the completion of the final step, as will be described later.

FIG. 3D is a representation of the source/drain region doping step 32 and the activation RTA step 33. FIG. 3D shows dopant deeply diffused regions 39.

The source/drain regions include the below-described source/drain extension regions and the dopant deeply diffused regions 39. The dopant in the source/drain regions is a Group V atom in the periodic table, such as arsenic (As) or phosphorus (P), or a molecule formed by combining a Group V atom for an N-type MOS transistor formed on a silicon substrate. On the other hand, a Group III atom in the periodic table, such as boron (B), or a molecule formed by combining a Group III atom, such as BF2 (boron fluoride) is used as the dopant for a P-type MOS transistor formed on a silicon substrate.

In the source/drain region doping step 32, a dopant is ionized and implanted into the dopant deeply diffused regions 39 of the source/drain regions with an ion implantation apparatus.

The activation RTA step 33 is performed in the same manner as the activation RTA described with reference to FIG. 2D.

By previously activating the dopant in the dopant deeply diffused regions 39, the source/drain extension regions, which require shallow junction, can be independently heat-treated to activate the dopant in the source/drain extension regions. Hence, the heat treatment for activating the dopant in the source/drain extension regions can be advantageously performed without adapting the heat treatment conditions to the activation of the dopant in the dopant deeply diffused region 39 and thus increasing the temperature or time of the heat treatment.

The activation RTA step 33 may be performed after the disposable side wall removing step 34, as will be described later.

FIG. 3E is a representation of the disposable side wall removing step 34. In the disposable side wall removing step 34, the disposable side wall 38 is removed by isotropic etching.

FIG. 4A is a flow chart showing the latter half of the method for manufacturing a semiconductor device according to Embodiment 1. FIG. 4A shows that the semiconductor device manufacturing method of Embodiment 1 further includes an offset forming step 40, an amorphizing ion implantation step 41, a pocket implant region doping step 42, a source/drain extension region doping step 43, an SPER step 44, a side wall forming step 45, and a silicide forming step 46.

FIG. 4B is a representation of the offset spacer forming step 40. The offset spacer forming step 40 includes the sub-step of deposing an insulating layer at a constant thickness and the sub-step of anisotropically etching the insulating layer. Thus, an offset spacer 47 is formed on the side walls of the gate electrode 37.

The offset spacer 47 has a smaller width than the disposable side wall 38. The name of offset spacer 47 comes from that a space is formed to slightly increase the width of the gate electrode 37 so as to complement the width (offset).

The offset spacer 47 is intended for use as a mask when a dopant is ion-implanted into the source/drain extension regions 50, as will be described later. The offset spacer 47 thus prevents the dopant implanted into the source/drain extension regions 50 from rounding and intruding the channel region of the MOS transistor.

FIG. 4C represents the amorphizing ion implantation step 41, the pocket implant region doping step 42, the source/drain extension region doping step 43, and the SPER step 44. FIG. 4C shows an amorphous layer 48, pocket implant regions 49, and the source/drain extension regions 50.

In the amorphizing ion implantation step 41, a type of ionized atom or molecule is implanted into the surface of the crystalline semiconductor with an ion implantation apparatus, so that an amorphous layer is formed at the surface of the crystalline semiconductor. The amorphous state results from the destruction of the semiconductor crystal by ion implantation.

The amorphous layer 48 is different from the amorphized layer shown in FIG. 2A in that the amorphous layer 48 has a larger depth than the pocket implant regions 49. The amorphous layer 48 is also different from the amorphized layer shown in FIG. 2A in that the amorphous layer 48 has substantially the same area as the entirety of the pocket implant regions 49.

The amorphous layer 48 is formed before the formation of the pocket implant regions 49 and the source/drain extension regions 50. This is because channeling can be prevented when the pocket implant regions 41 or the like are doped by ion implantation. Channeling refers to the phenomenon in which ions implanted into a portion not sufficiently blocking the entry of the implanted ions, that is, a portion between atoms forming the semiconductor crystal, take a long distance to enter the semiconductor substrate.

The atom or molecule used for amorphizing the semiconductor crystal is not the same as the atom or molecule as dopant for giving electroconductivity to the semiconductor. This is because a conductive layer may be formed in an undesired region at the surface of the semiconductor. In order to amorphize a region where a conductive layer is to be formed, a type of atom as dopant having the same conductive type may be ion-implanted.

When, for example, an amorphous layer is formed at the surface of the silicon crystal substrate, a type of homologous atom having a higher mass, such as germanium (Ge), may be used. Alternatively, a type of atom inactive even in silicon crystal and having a higher mass may be used, such as argon (Ar).

In the pocket implant region doping step 42, a type of atom or molecule as dopant for forming the pocket implant regions 49 is ionized and implanted into the pocket implant regions 49 with an ion implantation apparatus. The pocket implant regions 49 are in contact with the bottom of the source/drain extension regions 50 and have a depth from the bottom in the depth direction of the substrate. However, the dopant for the pocket implant regions 49 may enter not only the lower portions of the source/drain extension regions 50, but also their sides, because ion implantation of the dopant into the pocket implant region 49 is performed in a slanting direction forming an angle with respect to the surface of the substrate.

In this instance, the dopant for forming the pocket implant regions 49 has a conductive type opposite to the dopant in the source/drain regions. For an N-type transistor formed on a silicon semiconductor, for example, the dopant of the source and drain regions may be arsenic (As) and the dopant of the pocket implant regions 49 may be boron (B).

A source/drain region having an N-type conductivity and a P-type silicon substrate having a P-type conductivity may constitute a bipolar element and their bipolar behavior may cause a leakage current between the source and drain regions. Accordingly, the pocket implant regions 49 are intended to increase the dopant concentration in the region of the P-type silicon substrate adjacent to the source/drain regions, and to increase the threshold of the bipolar behavior.

In the source/drain extension region doping step 43, a type of atom or molecule as dopant for forming the source/drain extension regions 50 is ionized and implanted with an ion implantation apparatus. The source/drain extension regions 50 are disposed adjacent to the channel region of the MOS transistor and are each part of the source or drain region. The source/drain extension regions 50 have a depth of about 0.01 μm or 0.02 μm. Accordingly, the acceleration voltage of the ion implantation apparatus for implanting ions to form the source/drain extension regions 50 is low. For example, it is about 2 keV for ion implantation of arsenic (As), and is about 0.5 keV for ion implantation of boron (B).

The SPER step 44 is performed in the same manner as the low-temperature heat treatment step shown in FIG. 1. The SPER step 44 activates the dopants in the pocket implant regions 49 and the source/drain extension regions 50 even though a low-temperature heat treatment is performed. This is because the SPER step 44 produces the same effect as the low-temperature heat treatment step shown in FIG. 1.

FIG. 4D is a representation of the side wall forming step 45. FIG. 4D shows a side wall 51.

The side wall forming step 45 includes the sub-step of depositing an insulating layer at a constant thickness and the sub-step of anisotropically etching the insulating layer. Thus, the side wall 51 is completed.

FIG. 4E is a representation of a silicide forming step 46. FIG. 4E shows a silicide layer 52.

The silicide forming step 46 includes the sub-step of depositing a metal layer at a constant thickness, the sub-step of performing heat-treating to allow the metal layer to react with silicon, and the sub-step of removing the unreacted metal layer. Thus, the silicide layer 52 is completed.

While the steps shown in FIGS. 3A to 3E and 4A to 4E use an ion plantation apparatus to dope the source/drain extension regions, a dopant may be introduced into the semiconductor substrate by ionizing and biasing the dopant with, for example, a plasma apparatus. In order to diffuse the dopant in the source/drain regions, solid phase diffusion may be applied in which a material containing a large amount of dopant is deposited and then heat-treated to diffuse the dopant.

As shown in FIGS. 3A to 3E and 4A to 4E, the semiconductor device manufacturing method of Embodiment 1 is intended to manufacture a semiconductor device including a MOS transistor, and includes the step of forming the amorphous layer 48 at the surface of the semiconductor substrate so as to contain the pocket implant regions 49 and the source/drain extension regions 50. The semiconductor device manufacturing method of Embodiment 1 also includes the step of introducing a dopant to form the pocket implant regions 49. The semiconductor device manufacturing method of Embodiment 1 further includes the step of doping the source/drain extension regions disposed shallower than the pocket implant regions 49 and adjacent to the channel region of the MOS transistor. The semiconductor device manufacturing method of Embodiment 1 still further includes the step of recrystallizing the amorphous layer 48 by solid phase epitaxy technique to simultaneously activate the dopants in the pocket implant regions 49 and the source/drain extension regions 50. Moreover, the semiconductor device manufacturing method of Embodiment 1 includes the step of forming the gate insulating layer of the MOS transistor and the gate electrode of the MOS transistor. The formation of the amorphous surface layer and the introduction of dopant can be performed by ion implantation.

If the amorphous layer 48 has a depth beyond the bottom of the pocket implant regions 49, in general, the characteristics of the MOS transistor including the pocket implant regions 49 are degraded. Since the amorphous layer 48 rounds and intrudes the channel region, irregularities remain in the crystal lattice even though the amorphous layer is recrystallized by heat treatment. Consequently, the mobility of the carriers of the MOS transistor is reduced.

In the semiconductor device manufacturing method of Embodiment 1, however, the amorphous layer 48 is formed so as to contain the pocket implant regions 49 and the source/drain extension regions 50. Consequently, the dopants can be activated by performing heat treatment to the extent that solid phase epitaxy occurs.

Since the dopants in the pocket implant regions 49 and the source/drain extension regions 50 are taken in the crystal to an extent transcending their solubility limits, the semiconductor device manufacturing method of Embodiment 1 can produce the effect of reducing the resistance of the source/drain extension regions 50. Consequently, the reduction of the resistance of the source/drain extension regions 50 compensates the reduction in on-resistance of the MOS transistor resulting from the reduction in mobility of the carriers of the MOS transistor. Thus, the on-resistance of the MOS transistor is increased.

The semiconductor device manufacturing method of Embodiment 1 can advantageously activate the dopants in the pocket implant regions 49 and the source/drain extension regions 50 at a low temperature. The dopants in the pocket implant regions 49 and the source/drain extension regions 50 can thus be prevented from rediffusing. Consequently, the depth of the dopant junction in the source/drain extension region 50 can be shallow and the dopant distribution at the boundary can be sharp. In addition, the dopant concentration in the pocket implant regions 49 can be kept high, and accordingly, leakage current due to bipolar behavior can be reduced between the source region and the drain region.

### Embodiment 2

Embodiment 2 relates to a method for manufacturing a semiconductor device in which an amorphous layer is formed before forming the gate electrode, according to the same object as Embodiment 1.

The amorphous layer refers to a layer in which atoms are disorderly deposited, and may be called a non-crystalline layer. In the present embodiment, however, the amorphous layer may have a crystal lattice to some extent.

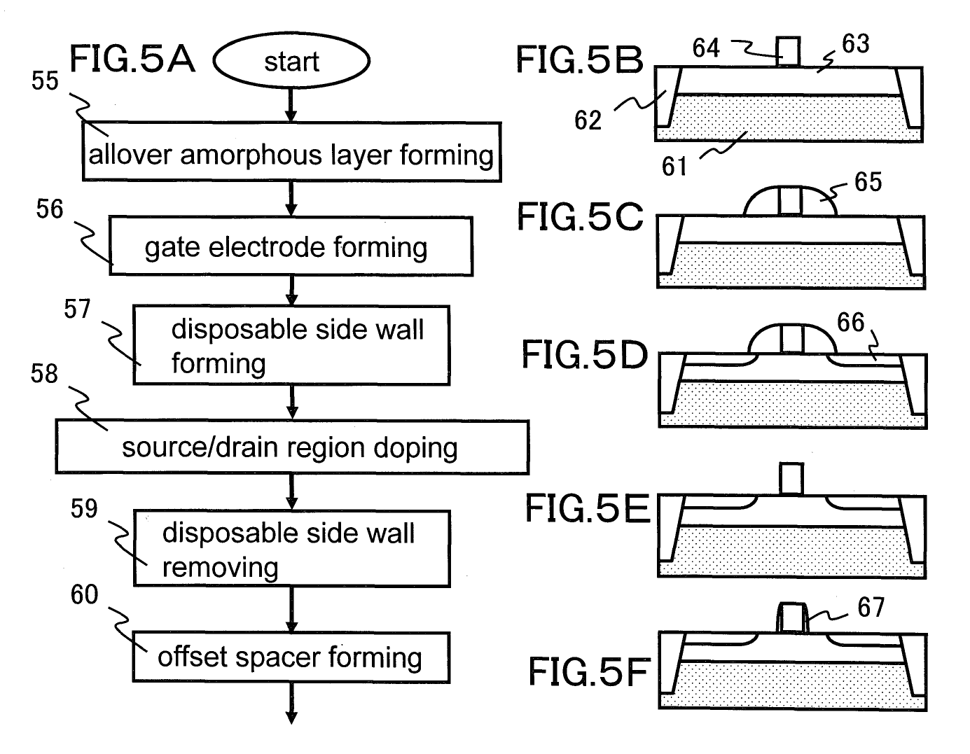

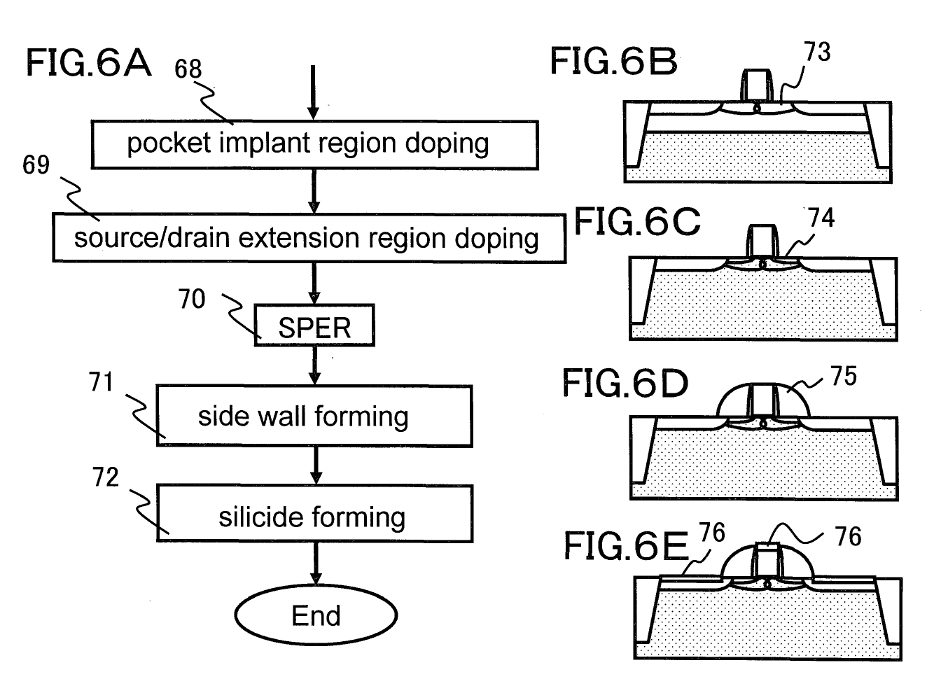

FIGS. 5A to 5F and 6A to 6E are representations of the method for manufacturing a semiconductor device according to Embodiment 2.

FIG. 5A is a flow chart showing the first half of the semiconductor device manufacturing method of Embodiment 2. FIG. 5A shows that the semiconductor device manufacturing method of Embodiment 2 includes an allover amorphous layer forming step 55, a gate electrode forming step 56, a disposable side wall forming step 57, a source/drain region doping step 58, a disposable side wall removing step 59, and an offset spacer forming step 60.

FIG. 5B is a representation of the allover amorphous layer forming step 55 and the gate electrode forming step 56. FIG. 5B shows a semiconductor substrate 61, and element isolation region 62, an amorphous layer 63, and a gate electrode 64.

The allover amorphous layer forming step 55 includes the sub-step of preparing the semiconductor substrate 61 having the element isolation region 62 and the sub-step of forming the amorphous layer 63.

The sub-step of preparing the semiconductor substrate 61 having the element isolation region 62 is performed in the same manner as the sub-step of preparing the semiconductor substrate shown in FIG. 3B.

In the sub-step of forming the amorphous layer 63, an amorphous layer is formed at the surface of the semiconductor crystal by implanting a type of ionized atom or molecule into the surface of the semiconductor crystal with an ion implantation apparatus. When, for example, the amorphous layer 63 is formed at the surface of a silicon crystal substrate, as in the amorphizing ion implantation step shown in FIG. 4C, a type of homologous atom having a higher mass, such as germanium (Ge), may be used as the atom or molecule to be ion-implanted. Alternatively, a type of atom inactive even in silicon crystal and having a higher mass may be use, such as argon (Ar).

However, the amorphous layer 63 shown in FIG. 5B is different from the amorphous layer shown in FIG. 4C in that the depth of the amorphous layer 63 is larger than that of the pocket implant regions and still larger than that of the dopant deeply diffused regions of the source/drain regions. The sub-step of forming the amorphous layer 63 shown in FIG. 5B is also different in that it is formed before forming the gate electrode 64.

The gate electrode forming step 56 includes the sub-step of forming a gate insulating layer, the sub-step of forming an electrical conductor layer for the gate electrode 64, the sub-step of etching the electrical conductor layer to form the gate electrode 64 of the MOS transistor.

The sub-step of forming a gate insulating layer must be performed at such a low temperature as the amorphous layer 63 is not crystallized. Preferably, the gate insulating layer is formed by, for example, depositing an insulating layer having a high dielectric constant, that is, a so-called high-k layer, at a low temperature.

The sub-step of forming an electrical conductor layer for the gate electrode 64, and the sub-step of etching the electrical conductor layer to form the gate electrode 64 of the MOS transistor are performed in the same manner as the steps shown in FIG. 3B. However, the sub-step of forming the electrical conductor for the gate electrode 64 is deferent in that it must be performed at such a low temperature as the amorphous layer 63 is not crystallized. Preferably, for example, the CVD (chemical vapor deposition) step of depositing the electrical conductor layer for the gate electrode 64 is performed at a low temperature, using a metal for the electrical conductor layer for the gate electrode 64. Alternatively, sputtering may be performed at a low temperature, using a metal for the electrical conductor layer for the gate electrode 64.

FIG. 5C is a representation of the disposable side wall forming step 57. FIG. 5C shows a disposable side wall 65. The disposable side wall forming step 57 includes the sub-step of depositing an insulating layer at a constant thickness and the sub-step of anisotropically etching the insulating layer, as in the step shown in FIG. 3C.

FIG. 5D is a representation of the source/drain region doping step 58. FIG. 5D shows dopant deeply diffused regions 66.

The source/drain regions each include a source or drain extension region described later and the dopant deeply diffused region 66. In the step described with reference to FIG. 5D, the dopant deeply diffused regions 66 are doped. A type of dopant to be implanted is selected as the dopant described with reference to FIG. 3D. An N-type dopant is used for an N-type transistor, and a P-type dopant is used for a P-type dopant.

FIG. 5E is a representation of the disposable side wall removing step 59. In the disposable side wall removing step 59, the disposable side wall 65 is removed by isotropic etching.

FIG. 5F is a representation of the offset spacer forming step 60. FIG. 5F shows an offset spacer 67.

The offset spacer forming step 60 is performed in the same manner as the offset spacer forming step shown in FIG. 4B.

FIG. 6A is a flow chart showing the latter half of the method for manufacturing a semiconductor device according to Embodiment 2. FIG. 6A shows that the semiconductor device manufacturing method of Embodiment 2 includes a pocket implant region doping step 68, a source/drain extension region doping step 69, an SPER step 70, a side wall forming step 71, and a silicide forming step 72.

FIG. 6B is a representation of the pocket implant region doping step 68. FIG. 6B shows pocket implant regions 73.

In the pocket implant region doping step 68, a type of atom or molecule as dopant is ionized and implanted into the pocket implant regions 73 with an ion implantation apparatus. The pocket implant regions 73 are in contact with the bottom of the source/drain extension regions and have a depth from the bottom in the depth direction of the substrate. However, the dopant for the pocket implant regions 73 may enter not only the lower portions of the source/drain extension regions 74, but also their sides, because ion implantation of the dopant into the pocket implant regions 73 is performed in a slanting direction forming an angle with respect to the surface of the substrate.

FIG. 6C is a representation of the source/drain extension region doping step 69 and the SPER step 70. FIG. 6C shows source/drain extension regions 74.

In the source/drain extension region doping step 69, a type of atom or molecule as dopant for forming the source/drain extension regions 74 is ionized and implanted with an ion implantation apparatus. The source/drain extension regions 74 are disposed adjacent to the channel region of the MOS transistor and are each part of the source or drain region.

The SPER step 70 is performed in the same manner as the low-temperature heat treatment step shown in FIG. 1. The SPER step 70 activates the dopants in the pocket implant regions 73 and the source/drain regions including the source/drain extension regions 74 even at a low temperature. The low-temperature heat treatment step shown in FIG. 1 and the above SPER step 70 produce the same effect.

FIG. 6D is a representation of the side wall forming step 71. FIG. 6D shows a side wall 75.

The side wall forming step 71 includes the sub-step of depositing an insulating layer at a constant thickness and the sub-step of anisotropically etching the insulating layer. Thus, the side wall 75 is completed. FIG. 6E is a representation of the silicide forming step 72. FIG. 6E shows a silicide layer 76.

The silicide forming step 72 includes the sub-step of depositing a metal layer at a constant thickness, the sub-step of performing heat treatment to allow the metal layer to react with silicon, and the sub-step of removing the unreacted metal layer. Thus, the silicide layer 76 is completed.

While the steps shown in FIGS. 5A to 5F and 6A to 6E use an ion implantation apparatus to dope the source/drain extension regions 74, a dopant may be introduced into the semiconductor substrate by ionizing and biasing the dopant with, for example, a plasma apparatus. In order to diffuse the dopant into the source/drain regions, solid phase diffusion may be applied in which a material containing a large amount of dopant is deposited and then heat-treated to diffuse the dopant.

As shown in FIGS. 5A to 5F and 6A to 6E, the semiconductor device manufacturing method of Embodiment 2 is intended to manufacture a semiconductor device including a MOS transistor, and includes the step of forming the amorphous layer 63 at the surface of the semiconductor substrate so as to contain the pocket implant regions 73, the source/drain extension regions 74, and the dopant deeply diffused regions 66 of the source/drain regions, after preparing the semiconductor substrate having the element isolation region.

The semiconductor device manufacturing method of Embodiment 2 also includes the step of introducing a dopant to form the dopant deeply diffused regions 66.

The semiconductor device manufacturing method of Embodiment 2 further includes the step of introducing a dopant to form the pocket implant regions 73.

In addition, the semiconductor device manufacturing method of Embodiment 2 includes the step of introducing a dopant into the source/drain extension regions 74 disposed shallower than the pocket implant regions 73 and adjacent to the channel region of the MOS transistor.

The semiconductor device manufacturing method of Embodiment 2 further includes the step of recrystallizing the amorphous surface layer by solid phase epitaxy technique to simultaneously activate the dopants in the pocket implant regions 73, the source/drain extension regions 74, and the dopant deeply diffused regions 59.

Moreover, the semiconductor device manufacturing method of Embodiment 2 includes the step of forming the gate insulating layer of the MOS transistor and the gate electrode of the MOS transistor. The formation of the amorphous layer 63 and the introduction of dopant can be performed by ion implantation.

If a MOS transistor is formed after forming the amorphous layer 63 having a larger depth than the dopant deeply diffused regions 66 of the source/drain regions over the entire surface of the semiconductor, in general, the characteristics of the MOS transistor are degraded. Since a channel region is formed in the amorphous layer 63, irregularities of the crystal lattice remain in the channel region even thought the amorphous layer is recrystallized by heat treatment, and consequently the mobility of the carriers of the MOS transistor is reduced.

In the semiconductor device manufacturing method of Embodiment 2, however, the amorphous layer 63 is formed so as to contain the pocket implant regions 73 and the source/drain extension regions 74. Accordingly, the dopants in these regions can be activated by heat treatment to the extent that solid phase epitaxy occurs.

Since the dopants in the pocket implant regions 73 and the source/drain extension regions 74 are taken in the crystal to an extent transcending their solubility limits, the semiconductor device manufacturing method of Embodiment 2 can produce the effect of reducing the resistance of the source/drain extension regions 62. Consequently, the reduction of the resistance of the source/drain extension regions 74 compensates the reduction in on-resistance of the MOS transistor resulting from the reduction in mobility of the carriers of the MOS transistor. Thus, the on-resistance of the MOS transistor is increased.

The semiconductor device manufacturing method of Embodiment 2 can advantageously activate the dopant in the pocket implant regions 73 and the dopant in the source/drain extension regions 74 at a low temperature. The dopant in the pocket implant regions 73 and the dopant in the source/drain extension regions 74 can thus be prevented from rediffusing. Consequently, the depth of the dopant junction in the source/drain extension region 74 can be shallow and the dopant distribution at the boundary can be sharp. In addition, the dopant concentration in the pocket implant regions 73 can be kept high, and accordingly, leakage current due to bipolar behavior can be reduced between the source region and the drain region.

### Embodiment 3

Embodiment 3 is intended to activate the dopant in the source/drain extension regions to an extent over the solid solubility of the dopant, and relates to a method for manufacturing a semiconductor device in which an amorphous layer is formed before doping the source/drain extension regions.

The amorphous layer refers to a layer in which atoms are disorderly deposited, and may be called a non-crystalline layer. In the present embodiment, however, the amorphous layer may have a crystal lattice to some extent.

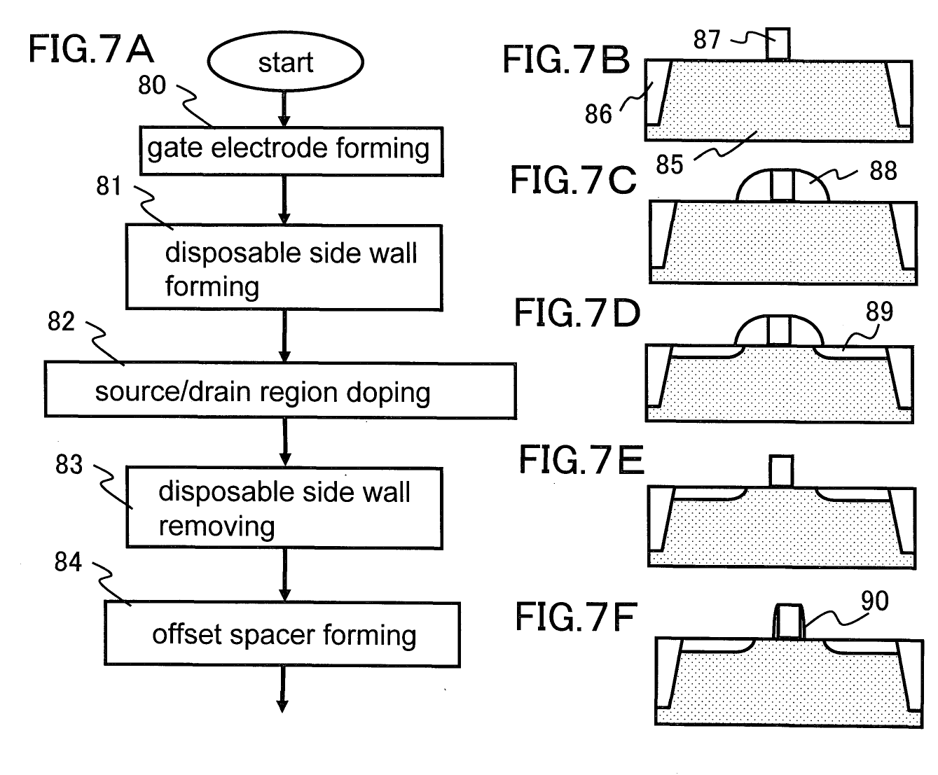

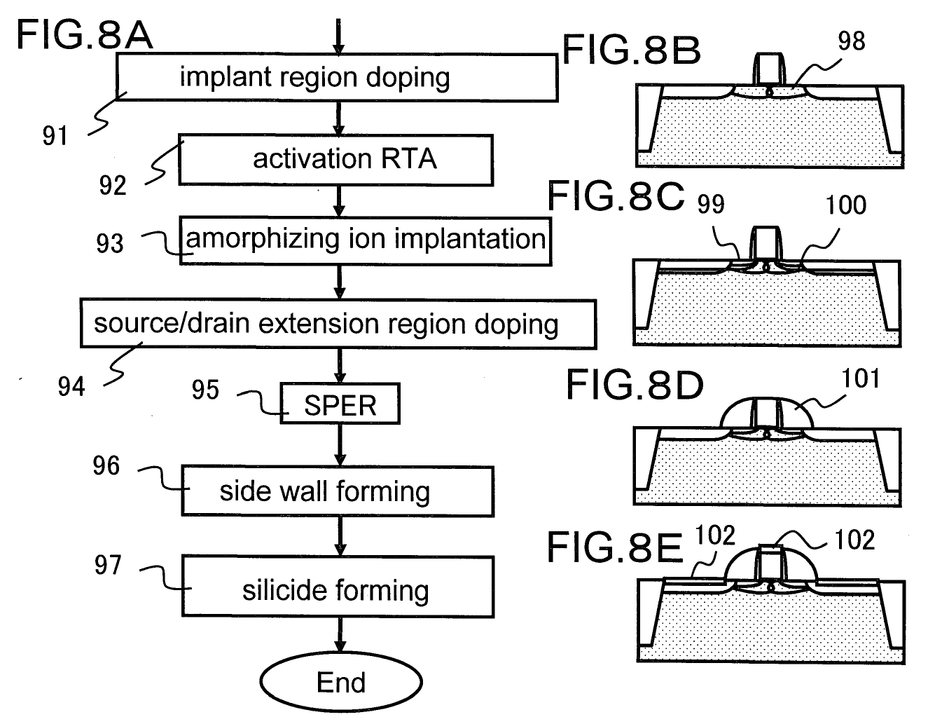

FIGS. 7A to 7F and 8A to 8E are representations of the method for manufacturing a semiconductor device according to Embodiment 3.

FIG. 7A is a flow chart showing the first half of the semiconductor device manufacturing method of Embodiment 3. FIG. 7A shows that the semiconductor device manufacturing method of Embodiment 3 includes a gate electrode forming step 80, a disposable side wall forming step 81, a source/drain region doping step 82, a disposable side wall removing step 83, and an offset spacer forming step 84.

FIG. 7B is a representation of the gate electrode forming step 80. FIG. 7B shows a semiconductor substrate 85, an element isolation region 86, and a gate electrode 87. The gate electrode forming step 80 includes the sub-step of preparing the semiconductor substrate 85 having the element isolation region 86, the sub-step of forming an gate insulating layer, the sub-step of forming an electrical conductor layer for the gate electrode 87, and the sub-step of etching the electrical conductor layer to form the gate electrode 87 of a MOS transistor.

The sub-step of preparing the semiconductor substrate 85 having the element isolation region 86 is performed in the same manner as the sub-step of preparing the semiconductor substrate shown in FIG. 5B. The sub-steps of forming an electrical conductor layer for the gate electrode 87 and etching the electrical conductor layer to form the gate electrode 87 of the MOS transistor are performed in the same manner as the sub-steps shown in FIG. 5B.

FIG. 7C is a representation of the disposable side wall forming step 81. FIG. 7C shows a disposable side wall 88.

The disposable side wall forming step 81 is the same as the step shown in FIG. 5C in that the disposable side wall forming step 81 includes the sub-step of depositing an insulating layer at a constant thickness and the sub-step of anisotropically etching the insulating layer.

FIG. 7D is a representation of the source/drain region doping step. FIG. 7D shows dopant deeply diffused regions 89. The source/drain regions each includes a source or drain extension region described later and the dopant deeply diffused region 89.

In the step described with reference to FIG. 7D, a dopant is implanted into the dopant deeply diffused regions 89. A type of dopant to be implanted is selected as the dopant described with reference to FIG. 5D, and depend on which type, N-type transistor or P-type transistor, is formed.

FIG. 7E is a representation of the disposable side wall removing step 83. In the disposable side wall removing step 83, the disposable side wall 88 is removed by isotropic etching.

FIG. 7F is a representation of the offset spacer forming step 84. FIG. 7F shows an offset spacer 90.

The offset spacer forming step 84 shown in FIG. 7F is performed in the same manner as the offset spacer forming step shown in 5F.

FIG. 8A is a flow chart showing the latter half of the semiconductor device manufacturing method of Embodiment 3. FIG. 8A shows that the semiconductor device manufacturing method of Embodiment 3 includes a pocket implant region doping step 91, an activation RTA step 92, an amorphizing ion implantation step 93, a source/drain extension region doping step 94, an SPER step, 95, side wall forming step 96, and a silicide forming step 97.

FIG. 8B is a representation of the pocket implant region doping step 91 and the activation RTA step 92. FIG. 8B shows pocket implant regions 98.

In the pocket implant region doping step 91, a type of tom or molecule as dopant is ionized and implanted into the pocket implant regions 98 with an ion implantation apparatus. The pocket implant regions 98 are in contact with the bottom of the source/drain extension regions and have a depth from the bottom in the depth direction of the substrate.

The activation RTA step 92 is performed in the same manner as the activation RTA step described with reference to FIG. 3.

FIG. 8C is a representation of the amorphizing ion implantation step 93, the source/drain extension region doping step 94, and the SPER step 95. FIG. 8C shows source/drain extension regions 99 and an amorphous layer 100.

In the amorphizing ion implantation step 93, an ionized atom or molecule is implanted at the surface of the crystalline semiconductor with an ion implantation apparatus, so that the amorphous layer 100 is formed at the surface of the crystalline semiconductor. When, for example, an amorphous layer is formed at the surface of the silicon crystal substrate, a type of homologous atom having a higher mass, such as germanium (Ge), may be used as the atom or molecule to be implanted, as in the amorphizing ion implantation step shown in FIG. 5B. Alternatively, a type of atom inactive even in silicon crystal and having a higher mass may be used, such as argon (Ar).

In the amorphizing ion implantation step 93, however, the amorphous layer 100 shown in FIG. 8C is different from the amorphous layer shown in FIG. 5B in that the depth of the amorphous layer is slightly larger than that of the dopant in the source/drain extension regions 99. The amorphizing ion implantation step 93 shown in FIG. 8C is also different in that it is performed after the activation of the dopant in the pocket implant regions 98.

In the source/drain extension region doping step, a type of atom or molecule as dopant for forming the source/drain extension regions 99 is ionized and implanted with an ion implantation apparatus. The source/drain extension regions 99 are disposed adjacent to the channel region of the MOS transistor and are each part of the source or drain region.

The SPER step 95 is performed in the same manner as the low-temperature heat treatment step shown in FIG. 1. The SPER step activates the dopant in the source/drain extension regions 99 even at a low temperature. The low-temperature heat treatment step shown in FIG. 1 and the above SPER step produce the same effect.

FIG. 8D is a representation of the side wall forming step 96, and shows a side wall 101.

The side wall forming step 96 includes the sub-step of depositing an insulating layer at a constant thickness and the sub-step of anisotropically etching the insulating layer. Thus, the side wall is completed.

FIG. 8E is a representation of the silicide forming step 97. The silicide forming step 97 includes the sub-step of depositing a metal layer at a constant thickness, the sub-step of performing heat treatment to allow the metal layer to react with silicon, and the sub-step of removing the unreacted metal layer. Thus, the silicide layer 102 is completed.

While the steps shown in FIGS. 7A to 7F and 8A to 8E use an ion implantation apparatus to dope the source/drain extension regions 99, a dopant may be introduced into the semiconductor substrate by ionizing and biasing the dopant with, for example, a plasma apparatus. In order to diffuse the dopant into the source/drain regions, solid phase diffusion may be applied in which a material containing a large amount of dopant is deposited and then heat-treated to diffuse the dopant.

As shown in FIGS. 7A to 7F and 8A to 8E, the semiconductor device manufacturing method of Embodiment 3 is intended to manufacture a semiconductor device including a MOS transistor, and includes the steps of preparing a semiconductor substrate having an element isolation region, then forming a gate insulating layer of the MOS transistor, and forming a gate electrode of the MOS transistor.

The semiconductor device manufacturing method of Embodiment 3 includes the step of introducing a dopant to form dopant deeply diffused regions 89.

The semiconductor device manufacturing method of Embodiment 3 further includes the step of introducing a dopant to form pocket implant regions 98.

The semiconductor device manufacturing method of Embodiment 3 also includes activating the dopants in the dopant deeply diffused regions 89 and the pocket implant regions 98.

In addition, the method includes the step of forming the amorphous layer 100 at the surface of the semiconductor substrate so as to contain the source/drain extension regions 99.

The semiconductor device manufacturing method of Embodiment 3 also includes the step of doping the source/drain extension regions 99 disposed shallower than the pocket implant regions 98 and adjacent to the channel region of the MOS transistor. The semiconductor device manufacturing method of Embodiment 3 also includes the step of recrystallizing the amorphous layer 100 by a solid-phase epitaxy technique to activate the dopant in the source/drain extension regions 99.

The formation of the amorphous layer 100 and the introduction of dopant can be performed by ion implantation.

In the semiconductor device manufacturing method of Embodiment 3, the amorphous layer 100 is formed so as to contain the source/drain extension regions 99. The dopant in this region is therefore activated at a temperature to the extent that solid phase epitaxy occurs.

Since the dopant in the source/drain extension regions 99 is taken in the crystal to an extent transcending the solubility limit, the semiconductor device manufacturing method of Embodiment 3 produces the effect of reducing the resistance of the source/drain extension regions 99. Thus, the increase of the resistance of the source/drain extension region 99 increases the on-resistance of the MOS transistor.

Furthermore, the semiconductor device manufacturing method of Embodiment 3 can advantageously activate the dopant in the source/drain extension regions 99 at a low temperature. The dopant in the source/drain extension regions 99 can thus be prevented from rediffusing. Consequently, the depth of the dopant junction in the source/drain extension region 99 can be shallow and the dopant distribution at the boundary can be sharp. Accordingly, the source/drain extension regions 99 do not round or intrude the channel region of the MOS transistor. Since the channel width can thus be maintained, the characteristics of the MOS transistor can be enhanced.

### Embodiment 4

Embodiment 4 is intended to activate the dopants in the source/drain regions and the pocket implant regions by heat treatment performed at a temperature to the extent that solid phase epitaxy occurs when the MOS transistor includes source/drain extension regions, “source/drain bridge regions” and pocket implant regions, and relates to a method for manufacturing a semiconductor device in which an amorphous layer is formed after forming the gate electrode.

In this embodiment, the source/drain regions each include a source or drain extension region, a source or drain bridge region, and a dopant deeply diffused region. The source/drain extension regions are disposed adjacent to the channel region of the MOS transistor and have a shallow junction depth. The “source/drain bridge regions” each connect the source/drain extension region and the dopant deeply diffused region. The “source/drain bridge regions” have a junction depth larger than the source/drain extension regions, but smaller than the dopant deeply diffused regions. Hence, the junction depth of the source/drain bridge regions is intermediate.

The amorphous layer refers to a layer in which atoms are disorderly deposited, and may be called a non-crystalline layer. In the present embodiment, however, the amorphous layer may have a crystal lattice to some extent.

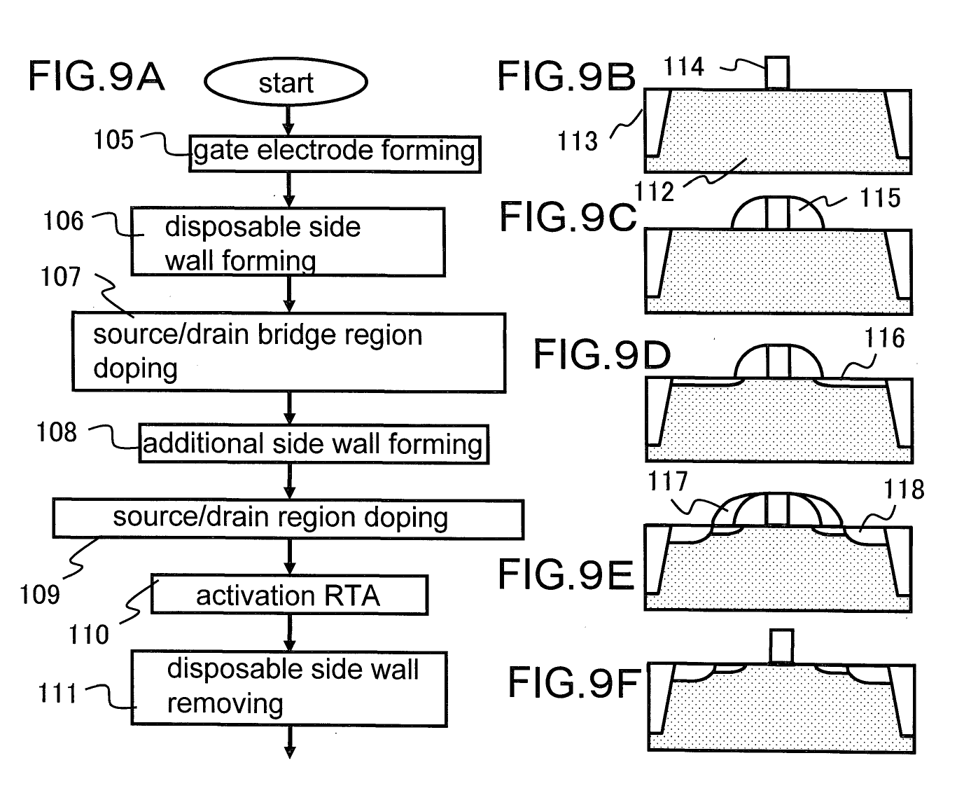

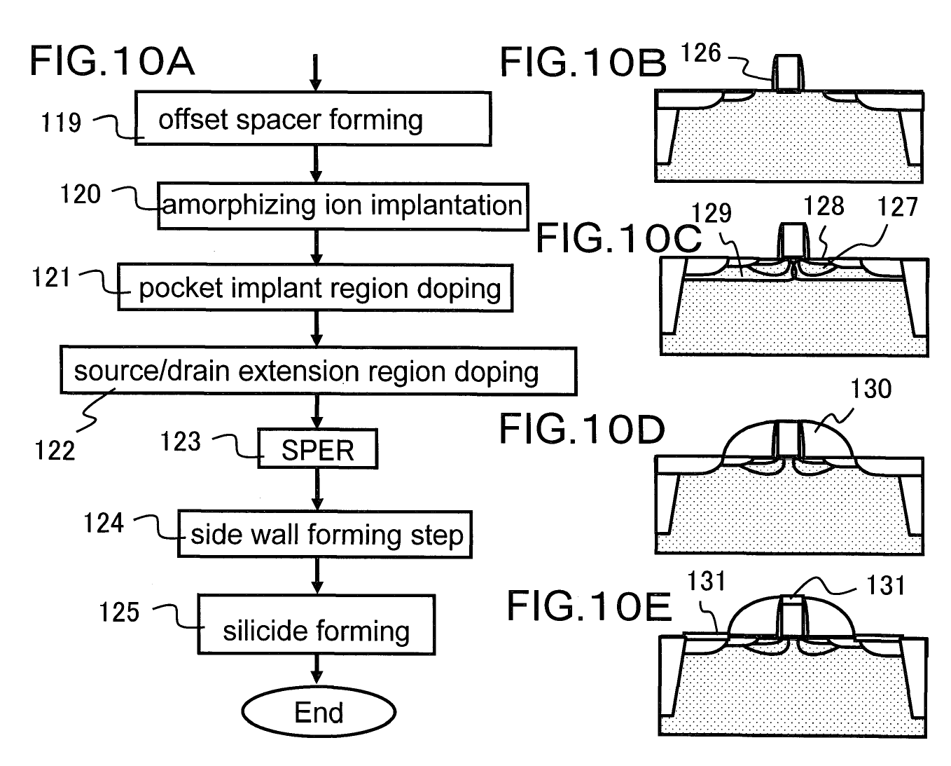

FIGS. 9A to 9F and 10A to 10E are representations of a method for manufacturing a semiconductor device according to Embodiment 4.

FIG. 9A is a flow chart showing the first half of the semiconductor device manufacturing method of Embodiment 4. The semiconductor device manufacturing method of Embodiment 4 includes a gate electrode forming step 105, a disposable side wall forming step 106, a source/drain bridge region doping step 107, an additional side wall forming step 108, a source/drain region doping step 109, an activation RTA step 110, and a disposable side wall removing step 111.

FIG. 9B is a representation of the gate electrode forming step 105. FIG. 9B shows a semiconductor substrate 112, an element isolation region 113, and a gate electrode 114.

The gate electrode forming step 105 includes the sub-step of preparing the semiconductor substrate 112 having an element isolation region 113, the sub-step of forming a gate insulating layer, the sub-step of forming an electrical conductor layer for the gate electrode 114, and the sub-step of etching the electrical conductor layer to form the gate electrode 114 of a MOS transistor.

The sub-step of preparing the semiconductor substrate 112 having the element isolation region 113 is performed in the same manner as the sub-step of preparing the semiconductor substrate shown in FIG. 3B. The sub-step of forming the electrical conductor layer and the sub-step of etching the electrical conductor layer to form the gate electrode 114 of a MOS transistor are performed in the same manner as the steps shown in FIG. 7B.

FIG. 9C is a representation of the disposable side wall forming step 106. FIG. 9C shows a disposable side wall 115.

The disposable side wall forming step 106 is the same as the step shown in FIG. 3C in including the sub-step of depositing an insulating layer at a constant thickness and the sub-step of anisotropically etching the insulating layer.

FIG. 9D is a representation of the source/drain bridge region doping step 107. FIG. 9D shows source/drain bridge regions 116. The source/drain bridge regions each 116 connect the source or drain extension region and the dopant deeply diffused region. The junction depth of the source/drain bride regions 116 is between the junction depths of the dopant deeply diffused regions and the source/drain extension regions.

In the step described with reference to FIG. 9D, the source/drain bridge regions 116 are doped. Since the source/drain bridge regions 117 are each part of the source or drain region, the type of dopant to be implanted is an N type for an N-type transistor, and a P type for a P-type transistor.

FIG. 9E is a representation of the additional side wall forming step 108, the source/drain region doping step 109, and the activation RTA step 110. FIG. 9E shows an additional side wall 117 and dopant deeply diffused regions 118.

In the additional side wall forming step 108, an insulating layer is deposited at a constant thickness, and is anisotropically etched to form the additional side wall 117 in addition to the disposable side wall 115.

In the source/drain region doping step 109, an N-type dopant for an N-type transistor or a P-type dopant for a P-type transistor is ion-implanted into the dopant deeply diffused regions 118.

The activation RTA step 110 performs heat treatment for a short time by RTA and is performed in the same manner as the activation RTA step described with reference to FIG. 3D.

FIG. 9F is a representation of the disposable side wall removing step 111. In the disposable side wall removing step 111, the disposable side wall 115 and the additional side wall 117 are removed by isotropic etching.

FIG. 10A is a flow chart showing the latter half of the semiconductor device manufacturing method of Embodiment 4. The semiconductor device manufacturing method of Embodiment 4 includes an offset spacer forming step 119, an amorphizing ion implantation step 120, a pocket implant region doping step 121, a source/drain extension region doping step 122, an SPER step 123, a side wall forming step 124, and a silicide forming step 125.

FIG. 10B is a representation of the offset spacer forming step 119. FIG. 10B shows an offset spacer 126. The offset spacer forming step 119 of Embodiment 4 is performed in the same manner as the offset spacer forming step shown in FIG. 4B.

FIG. 10C is a representation of the amorphizing ion implantation step 120, the pocket implant region doping step 121, and the source/drain extension region doping step 122, and shows an amorphous layer 127, source/drain extension regions 128, and pocket implant regions 129.

In the amorphizing ion implantation step 120, a type of ionized atom or molecule is implanted into the surface of the crystalline semiconductor with an ion implantation apparatus to form the amorphous layer 127 at the surface of the crystalline semiconductor. The depth of the amorphous layer 127 shown in FIG. 10C is the same as that of the amorphous layer shown in FIG. 4C in that it is larger than the depth of the dopant in the pocket implant regions 129. When an amorphous layer is formed at the surface of the silicon crystal substrate, a type of homologous atom in the periodic table having a higher mass may be used, such as germanium (Ge). Alternatively, a type of atom inactive even in silicon crystal and having a higher mass may be used, such as argon (Ar).

In the pocket implant region doping step 121, a type of atom or molecule as dopant is ionized and implanted into the pocket implant regions 129 with an ion implantation apparatus. The pocket implant regions 129 are in contact with the bottom of the source/drain extension regions 128, and have a depth from the bottom in the depth direction of the substrate. However, the dopant for the pocket implant regions 129 may enter not only the lower portions of the source/drain extension regions 128, but also their sides, because ion implantation of the dopant into the pocket implant regions 129 is performed in a slanting direction forming an angle with respect to the surface of the substrate.

In the source/drain extension region doping step 122, a dopant atom or molecule for forming the source/drain extension region 128 is ionized and implanted with an ion implantation apparatus. The source/drain extension regions 128 are disposed adjacent to the channel region of the MOS transistor, and are each part of the source or drain region.

FIG. 10D is a representation of the SPER step 123 and the side wall forming step 124. FIG. 10D shows a side wall 130.

The SPER step 123 is performed in the same manner as the dopant activation by solid-phase epitaxial regrowth shown in FIG. 1. The SPER step 123 activates the dopants in the pocket implant region 129 and the source/drain extension region 128 even though a low-temperature heat treatment is performed. This is because the SPER step 123 produces the same effect as the low-temperature heat treatment step shown in FIG. 1.

The side wall forming step 124 includes the sub-step of depositing an insulating layer at a constant thickness and the sub-step of anisotropically etching the insulating layer. Thus, the side wall 130 is completed.

FIG. 10E is a representation of the silicide forming step 125. FIG. 10E shows a silicide layer 131. The silicide forming step 125 includes the sub-step of depositing a metal layer at a constant thickness, the sub-step of performing heat treatment so as to allow the metal layer to react with silicon, and the sub-step of removing the metal layer. Thus, the silicide layer 131 is completed.

As shown in FIGS. 9A to 9F and 10A to 10E, the semiconductor device manufacturing method of Embodiment 4 is intended to manufacture a semiconductor device including a MOS transistor, and includes the step of forming the amorphous layer 127 at the surface of the semiconductor substrate so as to contain the pocket implant regions 129 and the source/drain extension regions 128 after the preparation of the semiconductor substrate having the element isolation region.

In the semiconductor device manufacturing method of Embodiment 4, the amorphous layer 127 forming step is performed immediately before ion-implanting a dopant into the pocket implant regions 129 and the source/drain extension regions 128. Alternatively, the amorphous layer 127 forming step may be performed after the formation of the element isolation region and before the formation of the gate electrode, as in the semiconductor device manufacturing method of Embodiment 2.

The semiconductor device manufacturing method of Embodiment 4 also includes the step of introducing a dopant for forming the dopant deeply diffused regions 118. The semiconductor device manufacturing method of Embodiment 4 also includes the step of introducing a dopant for forming the pocket implant regions 129. In addition, the semiconductor device manufacturing method of Embodiment 4 includes the step of doping the source/drain extension regions 128 disposed shallower than the pocket implant regions 129 and adjacent to the channel region of the MOS transistor.

The semiconductor device manufacturing method of Embodiment 4 further includes the step of doping the source/drain bridge regions 116. The semiconductor device manufacturing method of Embodiment 4 still further includes the step of recrystallizing the amorphous layer 127 by a solid phase epitaxy technique and thus simultaneously activating the dopants in the pocket implant regions 129 and the source/drain extension regions 128.

Moreover, the semiconductor device manufacturing method of Embodiment 4 includes the step of forming the gate insulating layer of the MOS transistor and the gate electrode of the MOS transistor. The formation of the amorphous layer 127 and the introduction of dopant can be performed by ion implantation.

If a MOS transistor is formed after forming the amorphous layer 127 having a depth beyond the bottom of the pocket implant regions 129 over the entire surface of the semiconductor, in general, the characteristics of the MOS transistor are degraded. Since the amorphous layer 127 is formed in the channel region of the MOS transistor, irregularities of the crystal lattice remain in the channel region even thought the amorphous layer is recrystallized by heat treatment, and consequently the mobility of the carriers of the MOS transistor is reduced.

In the semiconductor device manufacturing method of Embodiment 4, however, the amorphous layer 127 is formed so as to contain the pocket implant regions 129 and the source/drain extension regions 128. Consequently, the dopants in these regions can be activated by performing heat treatment to the extent that solid phase epitaxy occurs.

Since the dopants in the pocket implant regions 129 and the source/drain extension regions 128 are taken in the crystal to an extent transcending their solubility limits, the semiconductor device manufacturing method of Embodiment can produce the effect of reducing the resistance of the source/drain extension regions 128. Consequently, the reduction of the resistance of the source/drain extension regions 128 compensates the reduction in on-resistance of the MOS transistor resulting from the reduction in mobility of the carriers of the MOS transistor. Thus, the on-resistance of the MOS transistor is increased.

The semiconductor device manufacturing method of Embodiment 4 can advantageously activate the dopants in the pocket implant regions 129 and the source/drain extension regions 128 at a low temperature. The dopants in the pocket implant regions 129 and the source/drain extension regions 128 can thus be prevented from rediffusing. Consequently, the depth of the dopant junction in the source/drain extension region 128 can be shallow and the dopant distribution at the boundary can be sharp. In addition, the dopant concentration in the pocket implant regions 129 can be kept high, and accordingly, leakage current due to bipolar behavior can be reduced between the source region and the drain region.

1. A method for manufacturing a semiconductor device having a MOS transistor on a crystalline semiconductor substrate, the method comprising the step of:
doping a first dopant into source/drain extension regions adjacent to a channel region of the MOS transistor being included in source/drain regions of the MOS transistor;
doping a second dopant into pocket implant regions formed from the bottom of the source/drain extension regions in the depth direction in the crystalline semiconductor substrate;
forming an amorphous surface layer at the surface of the semiconductor substrate so as to overlap the source/drain extension regions and the pocket implant regions; and
recrystallizing the amorphous surface layer by a heat treatment to the crystalline semiconductor substrate.

2. The method according to claim 1, wherein the heat treatment is performed at temperature that solid phase epitaxy occurs.

3. The method according to claim 1, further comprising the steps of:
doping the first dopant into source/drain bridge regions adjacent to the source/drain extension regions of the MOS transistor, the source/drain bridge regions being included in the source/drain regions of the MOS transistor, a depth of the source/drain bridge regions being deeper than a depth of the source/drain extension regions; and
doping the first dopant into dopant deeply diffused regions adjacent to the source/drain bridge regions of the MOS transistor, the dopant deeply diffused regions being included in the source/drain regions of the MOS transistor, a depth of the dopant deeply diffused regions being deeper than a depth of the source/drain bridge regions.

4. The method according to claim 1, wherein doping the first dopant is performed by ion-implanting the first dopant into the source/drain extension regions, doping the second dopant is performed by ion-implanting the second dopant into the pocket implant regions, and forming an amorphous surface layer is performed by ion-implanting a homologous atom with a atom of which the crystalline semiconductor substrate is made, or an inactive atom in the crystalline semiconductor substrate.

5. The method according to claim 4, further comprising the steps of:
forming a gate electrode of the MOS transistor; and
forming a spacer on a side wall of the gate electrode, wherein ion-implanting the first dopant into the source/drain extension regions and a second doping step for doping a second dopant into pocket implant regions are performed between forming the gate electrode and forming a spacer on a side wall of the gate electrode.

6. A method for manufacturing a semiconductor device having a MOS transistor on a crystalline semiconductor substrate, the method comprising the steps of:
preparing a crystalline semiconductor substrate having an amorphous layer at a surface of crystalline semiconductor substrate;
ion-implanting a first dopant into source/drain extension regions adjacent to a channel region of the MOS transistor being included in source/drain regions of the MOS transistor, a depth of the amorphous layer being deeper than a depth of the source/drain extension regions;
ion-implanting a second dopant into pocket implant regions formed from the bottom of the source/drain extension regions in the depth direction in the crystalline semiconductor substrate, a depth of the amorphous layer being deeper than a depth of the pocket implant regions;
recrystallizing the amorphous surface layer by a heat treatment to the crystalline semiconductor substrate.

7. The method according to claim 6, wherein the heat treatment is performed at temperature that solid phase epitaxy occurs.

8. The method according to claim 6, further comprising the steps of:
ion-implanting the first dopant into source/drain bridge regions adjacent to the source/drain extension regions of the MOS transistor, the source/drain bridge regions being included in the source/drain regions of the MOS transistor, a depth of the source/drain bridge regions being deeper than a depth of the source/drain extension regions; and
ion-implanting the first dopant into dopant deeply diffused regions adjacent to the source/drain bridge regions of the MOS transistor, the dopant deeply diffused regions being included in the source/drain regions of the MOS transistor, a depth of the dopant deeply diffused regions being deeper than a depth of the source/drain bridge regions.
